(19) United States
(12) Patent Application Publication
(10) Pub. No.: US 2009/0107851 A1
(43) Pub. Date: Apr. 30, 2009

(54) Electrolytic polishing method of substrate

(76) Inventors: Akira Kodera, Kawasaki-shi (JP); Xinming Wang, Fujisawa-shi (JP); Itsuki Kobata, Fujisawa-shi (JP); Yasushi Toma, Fujisawa-shi (JP)

Correspondence Address: WENDEROTH, LIND & PONACK, L.L.P., 1030 15th Street, N.W.,, Suite 400 East, Washington, DC, 20005-1503, US

(21) Appl. No.: 12/285,615

(22) Filed: Oct. 9, 2008

(30) Foreign Application Priority Data
Oct. 10, 2007 (JP) 2007-264046
Sep. 19, 2008 (JP) 2008-241137

(51) Int. Cl. H01L 21/3063; H01L 21/67

(52) U.S. Cl. 205/656; 204/275.1; 204/230.2; 205/662

(57) ABSTRACT

An electrolytic polishing method of a substrate having a barrier film and an interconnect metal layer on a surface to be processed under the presence of an electrolytic solution, including a barrier film electrolytic polishing process which removes the barrier film by applying a voltage between a cathode and an anode, with the surface to be processed serving as the cathode, and causing relative motion between the surface to be processed and a polishing pad which faces and makes contact with the surface to be processed.

### BACKGROUND OF THE INVENTION

1. Field of the Invention

The present invention relates to an electrolytic polishing method of a substrate and an electrolytic polishing apparatus.

Priority is claimed on Japanese Patent Application No. 2007-264046, filed Oct. 10, 2007, and on Japanese Patent Application No. 2008-241137, filed Sep. 19, 2008, the content of which is incorporated herein by reference.

2. Description of Related Art

Instead of aluminum or an aluminum alloy, which has generally been used as a metal interconnect material for semiconductor integrated circuits, copper, which has low electrical resistance and high electromigration resistance, has recently been put into practical use. Copper interconnects are generally formed by a damascene method which includes filling copper, by plating, into via holes (connection holes) and trenches provided in an insulating film of a substrate, followed by CMP (chemical mechanical polishing) to remove a excess copper and a barrier film which prevents diffusion of copper and planarize the substrate surface. A CMP apparatus for use in such a process includes a polishing table with a polishing pad (polishing cloth) attached thereto, and a polishing head which holds a substrate, such as a semiconductor wafer, as a workpiece. The CMP apparatus polishes the surface of the substrate with the polishing pad into a flat, mirror-like surface by rotating the substrate, held by the polishing head, and the polishing table simultaneously while pressing the substrate against the polishing pad attached to the polishing table at a predetermined pressure and supplying an abrasive (slurry) to the sliding surfaces.

FIGS. 1A through 1D illustrate, in a sequence of processes, an example of a conventional production method of a substrate having copper interconnects. As shown in FIG. 1A, a lower-layer interconnect 14 of copper, surrounded by a barrier film 16, is formed in an insulating film (interlayer insulating film) 10 and a hard mask 12. Then, a Si—N barrier film 18, a first insulating film 20, a second insulating film 22, and a hard mask 24 are superimposed in this order. Simultaneously with this, a via hole 26 and a trench 28 are formed in these layers, e.g., by the lithography/etching technique. Thereafter, a barrier layer 30 is formed on an entire surface and a copper seed layer 32, which serves as a feeding layer in electroplating, is formed on the barrier layer 30.

A metal material, such as W, Ta/Ta_{X}N_{Y}, Ti_{X}N_{Y}, W×N_{Y}, W_{X}Si_{Y} (X and Y are each a numerical value that varies depending on the alloy), Ta_{X}Si_{Y}N_{Z}, Ti_{X}Si_{Y}Nd_{Z} (X, Y and Z are each a numerical value that varies depending on the alloy), Ru or Ru/WCN, is generally used for the barrier film 30 for preventing copper diffusion.

Next, as shown in FIG. 1B, copper 34 as an interconnect material is filled into the via hole 26 and the trench 28 of the substrate W while depositing copper 34 over the hard mask 24, for example, by plating. Thereafter, the copper 34 at the outermost surface of the substrate W and the seed film 32 are removed by chemical mechanical polishing (CMP) using an abrasive slurry, as shown in FIG. 1C, and then the barrier film 30 on the insulating film 22 is removed, whereby the polishing process is completed. An upper-layer interconnect 36 composed of the copper 34 is thus formed in the insulating films 20, 22, as shown in FIG. 1D.

In the CMP of copper, an insoluble oxide film of copper is formed on the surface of the copper by an oxidant and corrosion inhibitor and the like in the slurry, and polishing is considered to proceed by removing that with a polishing pad. For this reason, during the CMP process after a portion of the barrier film on the substrate is exposed and until all of the barrier film is exposed, excessive polishing of some of the copper occurs. Then, so-called dishing occurs in which dish-sized depressions are formed in the via holes and trenches. In the CMP of the barrier film that follows this, the chemical reactivity of the barrier film is low, and polishing is performed by a mechanical action mainly with abrasive grains. For this reason, it has been difficult to increase the selectivity ratio (the ratio of the polishing speed with another material) with copper. Therefore, there is the risk that the dishing that is generated in the copper CMP process will remain in that shape after the barrier film polishing process. Also, in even worse cases, the dishing will end up expanding. Also, it is difficult to increase the selectivity ratio with the insulating film of the substrate. This leads to the result of causing a phenomenon called erosion in which polishing of the insulating film continues even after the barrier film has been completely polished.

Moreover, in conventional CMP, the problem of polishing surface pressure has been pointed out. Accordingly, for metal interconnect polishing and barrier film polishing, a polishing method with low damage instead of the CMP process has been sought.

As one way to solve this problem there is a method that employs composite electrolytic polishing (electro-chemical mechanical polishing), which is a kind of electrolytic polishing and a technique utilizing a combination of the principles of CMP and electrolytic polishing, in processing and planarizing a metal surface. An exemplary composite electrolytic polishing method includes applying a voltage between a polishing table with a polishing pad (polishing cloth) attached thereto and a surface metal (copper) of a substrate (workpiece), such as a semiconductor wafer, held by a polishing head, with the polishing table serving as a cathode and the surface metal (copper) serving as an anode. The polishing table and the substrate are rotated while pressing the substrate that is held by the polishing head against the polishing pad at a fixed pressure. At this time, an electrolytic solution is supplied to the sliding surfaces of both, thereby polishing the surface metal of the substrate in an electrochemical mechanical manner.

The processing principle of electrolytic polishing consists in promoting oxidation and dissolution of a metal surface of a substrate (workpiece) by an electrolytic action, and promoting removal of an oxide film from the substrate by a polishing pad, thereby planarizing the metal surface. However, even in the case of polishing copper by composite electrolytic polishing, suppression of dishing is unavoidable.

Moreover, applying composite electrolytic polishing to a barrier film is difficult. This is because normally tantalum (Ta)-based metals and titanium-based metals that are used in the barrier film form a strong passive film on the surface. Accordingly, these metals behave like noble metals even if anode polarized, and so they are difficult to dissolve. In particular, tantalum forms an oxide film (Ta₂O₅) in a solution across all pH regions. As long as this oxide film is dense with good adhesion to metal tantalum, tantalum can behave as if a noble metal. In this case, the tantalum is almost completely corrosion-proof with respect to hydrofluoric acid, chlorides other than a dense alkaline solution, sulfuric acid, phosphoric acid, nitric acid, and aqua regia, and anode dissolution is difficult.

Japanese Unexamined Patent Application No. 2004-276219 discloses a method electrolytic polishing using an electrolytic processing liquid of a barrier layer that includes either an alkaline solution or fluorine series solution and inhibitor. However, in this method, because the entire substrate serves as an anode, there is the problem that the interconnect metal (for example, copper), which dissolves more easily than the barrier film preferentially dissolves, and so dishing cannot be avoided.

Also, even assuming a barrier metal in which dissolution removal is possible by anode polarization, the fact that an interconnect metal such as copper that resists dissolution ends up simultaneously dissolving is one of the reasons why composite electrolytic polishing of the barrier film is difficult.

As stated above, in the polishing process of a barrier film by CMP or composite electrolytic polishing, increasing the selectivity ratio with copper is difficult, and relieving the dishing that occurs in the copper polishing process is difficult. Also, in the barrier polishing process by CMP, it is difficult to suppress erosion in which the insulating film of the substrate is excessively polished. Moreover, the problem also arises of causing damage to a low-k film as a result of polishing with a high surface pressure. Accordingly, there is a need for a new polishing method.

The present invention was achieved in view of the above circumstances, and an object thereof is to provide a polishing method that, in polishing of a conductive material such as a barrier film that is formed on a substrate surface in a semiconductor manufacturing process, is capable of exposing an insulating film by removing the unnecessary conductive material without causing dishing and erosion and without causing damage to the insulating film layer.

### SUMMARY OF THE INVENTION

The present inventors have arrived at the present invention as the result of studies directed toward working out a solution to these issues, with the discovery that it is possible to achieve the aforementioned object by applying a voltage between a cathode and an anode, with a surface to be processed that has a barrier film and a metal interconnect layer serving as the cathode, to cause a reduction reaction and causing relative motion between a polishing pad that makes contact with the surface to be processed and the surface to be processed.

(1) One aspect of the present invention provides the following: an electrolytic polishing method of a substrate having a barrier film and an interconnect metal layer on a surface to be processed under the presence of an electrolytic solution, the method including a barrier film electrolytic polishing process which removes the barrier film by applying a voltage between a cathode and an anode, with the surface to be processed serving as the cathode, and causing relative motion between the surface to be processed and a polishing pad which faces and makes contact with the surface to be processed.

According to the method of the present invention, it is possible to substantially remove only the barrier film without causing dishing or erosion in the barrier film electrolytic polishing process and without causing damage to an interlayer insulating film.

Also, according to this method, even if a passive film is formed on the barrier film surface prior to starting electrolytic polishing of the barrier film, the passive film is reduced by applying a voltage with the barrier film serving as a cathode. If a suitable electrolyte liquid is interposed, the passive film is removed by contact with a polishing pad and relative motion therebetween. After the passive film is removed, a state arises in which the barrier film is easily dissolved and removed by being polished by contact with a polishing pad under imposition of the electrolytic solution and relative motion therebetween, and is removed by polishing with the polishing pad. On the other hand, even if the metal interconnect layer is exposed on the surface to be processed simultaneously with the barrier film, since polishing removal of the metal interconnect layer is hindered by the reduction action, there is hardly any polishing removal by contact with the polishing pad. Accordingly, it is possible to essentially remove only the barrier film. For example, in the case of having polished a substrate in which dishing of a depth equal to the thickness of the barrier film is formed on the surface of the metal interconnect layer, the substrate surface after polishing becomes a flat surface.

(2) The electrolytic polishing method of a substrate of the present invention may be performed in the following manner: in the barrier film electrolytic polishing process, the voltage which is applied between the cathode and the anode is 0.01 to 500 V.

(3) The electrolytic polishing method of a substrate of the present invention may be performed in the following manner: in the barrier film electrolytic polishing process, along with the barrier film being removed, the metal interconnect layer is reduced.

The metal interconnect layer has defects such as scratches in addition to having films such as an oxide film and a corrosion inhibitor formed on the surface by the polishing of the previous process. By reducing the metal interconnect layer, it is possible to remove the oxide film and a corrosion inhibitor that are formed on the metal interconnect layer and repair the defects such as scratches on the surface of the metal interconnect layer. Thereby, it is possible to reduce problems in the next process. The problems in the next process are for example problems of the polishing speed not stabilizing during the polishing of the metal interconnect layer due to the surface films, and problems of washing of the surface film being difficult in the washing of the substrate.

(4) The electrolytic polishing method of a substrate of the present invention may be performed in the following manner: the electrolytic polishing method further includes, before or after the barrier film electrolytic polishing process, a metal interconnect layer electrolytic polishing process which removes the metal interconnect layer which is exposed by applying a voltage between a second anode and a second cathode, with the surface to be processed of the substrate serving as the second anode.

In this case, it is possible to minimize the damage to the interlayer insulating film with a low mechanical strength (for example, a low-k film) by performing electrolytic polishing of the metal interconnect layer as a preceding process or succeeding process of the barrier film electrolytic polishing process.

(5) The electrolytic polishing method of a substrate of the present invention may be performed in the following manner: the barrier film is composed of a material selected from the group consisting of tungsten, titanium, tantalum, manganese, vanadium, chromium, or their alloys, nitride, carbide, nitrogen carbide, nitrogen silicide, or a combination thereof, and the metal interconnect layer is composed of a material selected from the group consisting of gold, silver, copper, ruthenium, rhodium, platinum, iridium or their alloys.

(6) The electrolytic polishing method of a substrate of the present invention may be performed as follows: the electrolytic solution which is used in the barrier film electrolytic polishing process includes at least one of the following electrolytes or a combination thereof: hydrofluoric acid, potassium fluoride, lithium fluoride, ammonium fluoride, hydrochloric acid, hydrobromic acid, hydroiodic acid, sulfurous acid, sulfuric acid, disulfuric acid, alkyl sulfonic acid, benzenesulfonic acid, nitric acid, orthophosphoric acid, diphosphoric acid, triphosphoric acid, polyphosphoric acid, hypophosphoric acid, phosphorous acid, phosphinic acid, amino trimethylene phosphonic acid, hexafluorosilicic acid, hexafluorosilicic acid ammonium fluoride, hexafluorosilicic acid potassium, hexa fluorophosphoric acid, hexa fluorophosphoric acid ammonium, hexa fluorophosphoric acid potassium, hexa fluorophosphoric acid lithium, tetrafluoroboric acid, tetrafluoroboric acid tetra n-butyl ammonium, tetrafluoroboric acid copper (II), phthalic acid, tetraboric acid and their salts, potassium hydroxide, sodium hydroxide, lithium hydroxide, ammonia, trimethylammonium hydroxide, and 2-hidoroxyethyl-trimethyl ammonium hydroxide.

(7) The electrolytic polishing method of a substrate of the present invention may be performed in the following manner: the electrolytic solution which is used in the barrier film electrolytic polishing process further includes at least one of the following complexing agents or a combination thereof: ethylenediaminetetraacetic acid (EDTA), dihydroxy ethyl ethylenediamine diacetic acid (DHEDDA), 1,3-propanediamine 4 acetic acid (1,3-PDTA), diethylenetriamine 5 acetic acid (DTPA), triethylenetetramine 6 acetic acid (TTHA), nitrilotriacetic acid (NTA), hydroxyethyl iminodiacetic acid (HIMDA), L-aspartic acid N,N-diacetic acid (ASDA), amino trimethylene phosphonic acid (NTMP), hydroxylethyl ethylenediamine tri-acetic acid (HEDTA), hydroxy ethylidene diphosphoric acid (HEDP), nitrilotris (methylene) phosphonic acid (NTMP), phosphonobutane tricarboxylic acid (PBTC), N,N,N′,N′-tetrakis (phosphonomethyl)ethylenediamine (EDTMP).

(8) Another aspect of the present invention provides the following: an electrolytic polishing method of a substrate having an interlayer insulating film, a barrier film, and an interconnect metal layer, the method including: a metal interconnect electrolytic polishing process which removes the metal interconnect layer and exposes the barrier film by a process which includes at least either one of applying a chemical mechanical polishing to the substrate, etching the substrate, or performing an electrolytic polishing using the substrate with the exposed metal interconnect layer as an anode; and a barrier film electrolytic polishing process which removes the barrier film, by applying a voltage under the presence of an electrolytic solution, between a cathode and a second anode, with the substrate in which the barrier film is exposed serving as the cathode, and causing relative motion between the surface to be processed on the substrate and a polishing pad which faces and makes contact with the surface to be processed.

In the aforementioned method, it is possible to inhibit dishing in the eventual metal interconnect layer to a minimum by controlling the polishing amount of the metal interconnect.

(9) In one embodiment of the present invention, the electrolytic polishing method of a substrate may be performed as follows: the method further includes a process which removes the metal interconnect layer which remains as a projection portion on the surface to be processed, and planarizes the surface of the substrate by a process which includes at least either one of applying chemical mechanical polishing to the substrate, etching the substrate, or performing an electrolytic polishing using the substrate as an anode.

In this way, it is possible to planarize the surface by polishing removal or etching removal after the barrier film polishing process in the case of the metal interconnect layer remaining as a projection portion on the surface to be processed when the barrier film polishing process is completed.

(10) In one embodiment of the present invention, the electrolytic polishing method of a substrate may be performed as follows: in the barrier film electrolytic polishing process, the voltage which is applied between the substrate and the anode is 0.01 to 500 V.

(11) In one embodiment of the present invention, the electrolytic polishing method of a substrate may be performed as follows: in the barrier film electrolytic polishing process, the barrier film is removed, and the metal interconnect layer is reduced.

(12) In one embodiment of the present invention, the electrolytic polishing method of a substrate may be performed as follows: the metal interconnect electrolytic polishing process is an electrolytic polishing process which is performed by applying a voltage of 1 to 50 V between the substrate and the cathode.

(13) In one embodiment of the present invention, the electrolytic polishing method of a substrate may be performed as follows: the barrier film is composed of a material selected from the group consisting of tungsten, titanium, tantalum, manganese, vanadium, chromium, or their alloy, nitride, carbide, nitrogen carbide, nitrogen silicide, and a combination of these, and the metal interconnect layer is composed of a material selected from the group consisting of gold, silver, copper, ruthenium, rhodium, platinum, iridium, or their alloy.

(14) In one embodiment of the present invention, the electrolytic polishing method of a substrate may be performed as follows: the electrolytic solution which is used in the barrier film electrolytic polishing process includes at least one of the following electrolytes or a combination thereof: hydrofluoric acid, potassium fluoride, lithium fluoride, ammonium fluoride, hydrochloric acid, hydrobromic acid, hydroiodic acid, sulfurous acid, sulfinuric acid, disulfuric acid, alkyl sulfonic acid, benzenesulfonic acid, nitric acid, orthophosphoric acid, diphosphoric acid, triphosphoric acid, polyphosphoric acid, hypophosphoric acid, phosphorous acid, phosphinic acid, amino trimethylene phosphonic acid, hexafluorosilicic acid, hexafluorosilicic acid ammonium fluoride, hexafluorosilicic acid potassium, hexa fluorophosphoric acid, hexa fluorophosphoric acid ammonium, hexa fluorophosphoric acid potassium, hexa fluorophosphoric acid lithium, tetrafluoroboric acid, tetrafluoroboric acid tetra n-butyl ammonium, tetrafluoroboric acid copper (II), phthalic acid, tetraboric acid and their salts, potassium hydroxide, sodium hydroxide, lithium hydroxide, ammonia, trimethylammonium hydroxide, and 2-hidoroxyethyl-trimethyl ammonium hydroxide.

(15) In one embodiment of the present invention, the electrolytic polishing method of a substrate may be performed as follows: the electrolytic solution which is used in the barrier film electrolytic polishing process further includes at least one of the following complexing agents or a combination thereof: ethylenediaminetetraacetic acid (EDTA), dihydroxy ethyl ethylenediamine diacetic acid (DHEDDA), 1,3-propanediamine 4 acetic acid (1,3-PDTA), diethylenetriamine 5 acetic acid (DTPA), triethylenetetramine 6 acetic acid (TTHA), nitrilotriacetic acid (NTA), hydroxyethyl iminodiacetic acid (HIMDA), L-aspartic acid N,N-diacetic acid (ASDA), amino trimethylene phosphonic acid (NTMP), hydroxyl-ethyl ethylenediamine tri-acetic acid (HEDTA), hydroxy ethylidene diphosphoric acid (HEDP), nitrilotris (methylene) phosphonic acid (NTMP), phosphonobutane tricarboxylic acid (PBTC), N,N,N′,N′-tetrakis (phosphonomethyl)ethylenediamine (EDTMP).

(16) Another aspect of the present invention provides the following: an apparatus for electrolytic polishing, which immerses a substrate having a barrier film and a metal interconnect layer on a side of a surface to be processed, in an electrolytic solution, and conduct electrochemical machining, thereby conducting an electrolytic polishing process, the apparatus comprising: a polishing table for placing the polishing pad on the upper surface thereof; an electrolytic solution supply nozzle which is capable of supplying an electrolytic solution on the polishing pad; a substrate holder for holding the substrate; a drive mechanism for driving the substrate holder; and a processing electrode and a feeding electrode which are connected to a power supply, wherein the apparatus removes the barrier film of the substrate by applying a voltage between a cathode and an anode, with the surface to be processed of the substrate serving as the anode and the processing electrode serving as the cathode, and causing relative motion between the substrate and the polishing pad by driving the substrate holder with the drive mechanism.

According to the aforementioned electrolytic polishing apparatus, it is possible to favorably perform the electrolytic polishing method of the substrate.

(17) In one embodiment of the present invention, the apparatus may be constituted in the following way: the apparatus further includes a sensor which detects the film thickness of the conductive material of the surface to be processed of the substrate and emits an output signal; and a control portion which performs control calculation processing with the output signal from the sensor serving as an input signal, and based on the control calculation processing, emits a control signal.

Thereby, feedback control becomes possible.

A change in the film thickness of the conductive material (that is, the metal interconnect layer) of the substrate that is the polishing object and the exposure state of the barrier film can for example be monitored by sensing changes in eddy currents, and with this serving as feedback, it is possible to prevent excess polishing of the metal interconnect layer that is embedded in trenches or the like after the barrier film has started to be exposed by controlling a voltage that is applied for example between the metal interconnect layer and a counter electrode.

### BRIEF DESCRIPTION OF THE DRAWINGS

FIG. 1A is a sectional view that shows an example of a conventional process for forming interconnects.

FIG. 1B is a sectional view that shows an example of a conventional process for forming interconnects.

FIG. 1C is a sectional view that shows an example of a conventional process for forming interconnects.

FIG. 1D is a sectional view that shows an example of a conventional process for forming interconnects.

FIG. 2 is a sectional view that shows the outline of a structure of an electrolytic polishing apparatus that is used in the electrolytic polishing method of a substrate of the present invention.

FIG. 3 is a plan view that shows the processing chamber (electrolytic polishing chamber) of the electrolytic polishing apparatus of FIG. 2

FIG. 4 is a process schematic view that schematically shows an embodiment of the electrolytic polishing method of a substrate of the present invention.

FIG. 5 is a process schematic view that schematically shows another embodiment of the electrolytic polishing method of a substrate of the present invention.

FIG. 6 is a cross-sectional view that shows another example of an electrolytic polishing apparatus that is used in the electrolytic polishing method of a substrate of the present invention.

FIG. 7 is an enlarged view of the substrate holder portion of the electrolytic polishing apparatus of FIG. 6.

FIG. 8 is a cross-sectional view that shows still another example of an electrolytic polishing apparatus that is used in the electrolytic polishing method of a substrate of the present invention.

FIG. 9 is an enlarged view of the apparatus of FIG. 8.

### DETAILED DESCRIPTION OF THE INVENTION

As a substrate to which the electrolytic polishing method of a substrate of this invention can be applied, it is possible to preferably include an interconnect substrate that has a multilayer interconnect structure, such as a semiconductor device and a liquid crystal display. Usually, in an interconnect substrate used for a semiconductor device and the like, an interlayer insulating film, a barrier film, and a metal interconnect layer are formed on a base material layer such as monocrystal silicon, polycrystal silicon, silica, and glass.

Note that in the present specification, “anode” refers to an electrode in which electrons flow from an electrolytic solution toward an electrode. “Cathode” refers to an electrode in which electrons flow from an electrode to an electrolytic solution.

Also, “electrolytic polishing” is a polishing method that involves applying a voltage between a conductive material serving as a workpiece and a counter electrode, and causing current to flow between the two with an electrolytic polishing liquid to process the conductive material by an electrochemical action. In electrolytic polishing, there is a method that involves bringing a polishing member such as a polishing pad or the like into contact with the workpiece for the purpose of polishing and causing them to move relative to each other, and a method that does not use a polishing member. “Composite electrolytic polishing” is a polishing method that, among the above methods, applies a voltage between a conductive material serving as a workpiece and a counter electrode, and causes current to flow between the two with an electrolytic polishing liquid to process the workpiece by an electrochemical action and mechanical action such as contact and relative motion or the like with the polishing member. In the present invention, “composite electrolytic polishing” is included in “electrolytic polishing” in the above manner. Note that in this industry, composite electrolytic polishing is referred to as electrochemical mechanical polishing or electrolytic composite polishing.

Also, “chemical mechanical polishing (CMP)” is a wet mechanochemical processing method which utilizes a solid-liquid reaction between a workpiece and a polishing liquid, and was developed with the aim of attaining planarization of VLSI devices (planarizing of interlevel films in a multilevel interconnect structure).

“Etching processing” in the present invention denotes wet etching, and involves dissolving a solid material such as a metal or resin and the like that comes into contact with a solution by the corrosive and solvent action of the chemicals in the solution.

In the present invention, it is possible to use SiO₂, SiOF, SiOC or so-called “low-k” materials without any particular restrictions as the formation material of the interlayer insulating film.

Table 1 shows with a standard hydrogen electrode (SHE) basis the oxidation reduction potential (E⁰) of the formation material of a barrier film and the formation material of a metal interconnect layer to which the electrolytic polishing method of a substrate of the present invention (substrate electrolytic polishing method) can be applied.

TABLE 1
Oxidation Reduction Potential of Formation Material
of Barrier Film and Metal Interconnect Layer

| Barrier Film | | Metal Interconnect Layer | |
|---|---|---|---|
| Formation Material | | Formation Material | |
| | Oxidation | | Oxidation |
| | Reduction | | Reduction |
| | Potential | | Potential |
| | (E⁰) | | (E⁰) |
| Cell Reaction | (V vs. SHE) | Cell Reaction | (V vs. SHE) |
| Ti²⁺ + 2e = Ti | −1.63 V | Au⁺ + e = Au | 1.68 V |
| Ta⁵⁺ + 5e = Ta | −1.12 V | Ag⁺ + e = Ag | 0.80 V |
| V²⁺ + 2e = V | −1.13 V | Cu²⁺ + 2e = Cu | 0.34 V |
| Zr⁴⁺ + 4e = Zr | −1.53 V | Ru²⁺ + 2e = Ru | 0.46 V |
| Nb³⁺ + 3e = Nb | −1.1 V | Rh³⁺ + 3e = Rh | 0.76 V |
| WO₄²⁻ + 4H₂O + | −1.07 V | Ir³⁺ + 3e = Ir | 1.16 V |
| 6e = W + 8OH⁻ | | | |
| Cr²⁺ + 2e = Cr | −0.79 V | Pt²⁺ + 2e = Pt | 1.19 V |
| Mn²⁺ + 2e = Mn | −1.18 V | | |
| Co²⁺ + 2e = Co | −0.29 V | | |
| Hf⁴⁺ + 4e = Hf | −1.7 V | | |
| Mo³⁺ + 3e = Mo | −0.2 V | | |

Preferred embodiments of the present invention will now be described with reference to the drawings. The following description illustrates the process of removing an unnecessary portion of a copper film (including a seed film) as an interconnect material, formed on a barrier film of a substrate as a polishing object, thereby exposing the barrier film, and the process of polishing and removing the exposed barrier film as a polishing object.

### FIRST EMBODIMENT

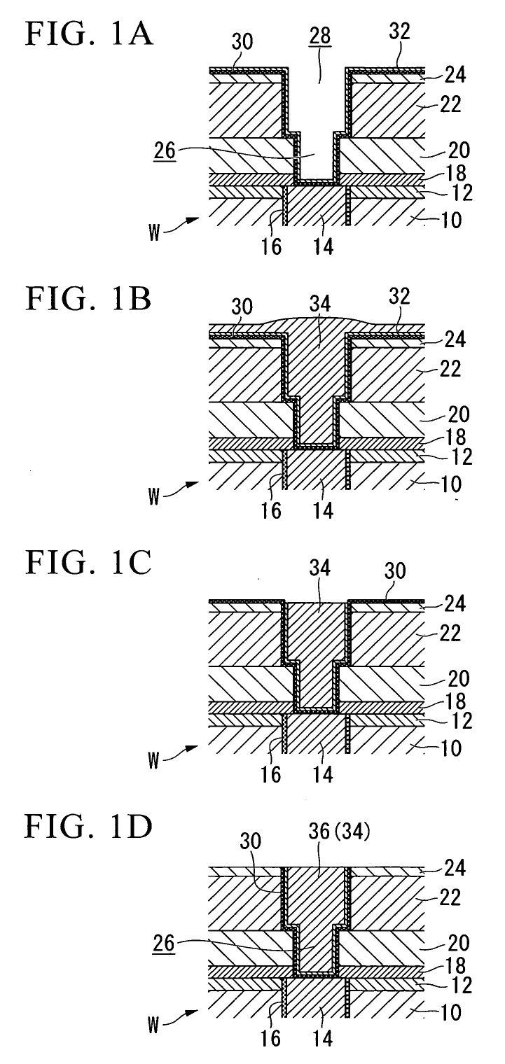

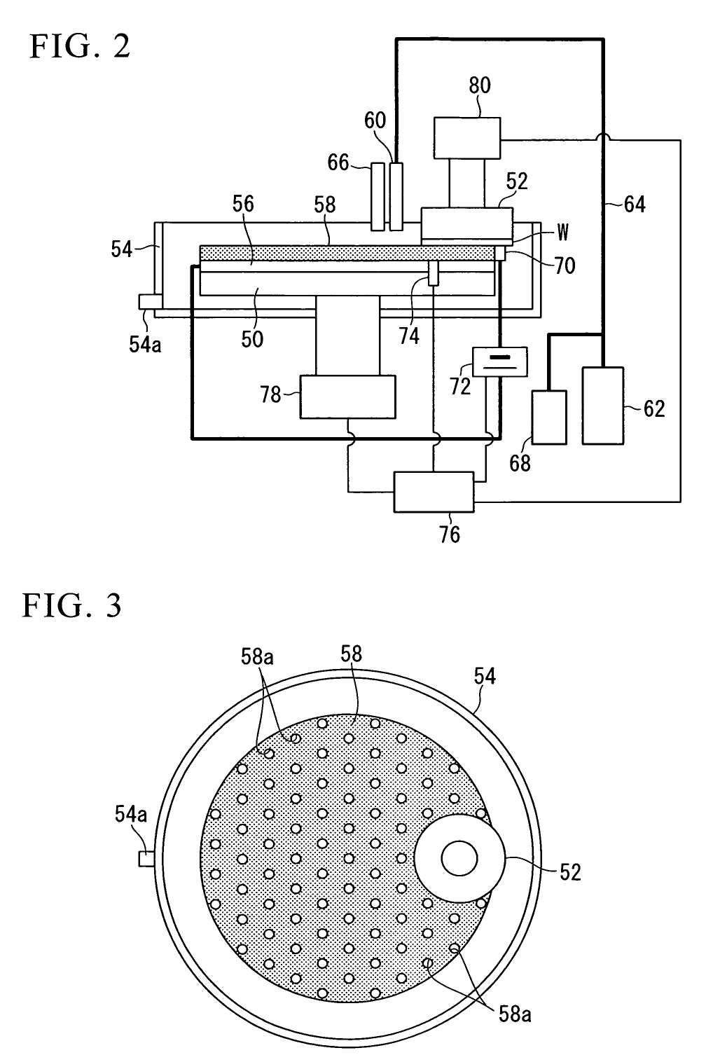

FIG. 2 is a cross-sectional view that shows an electrolytic polishing apparatus, and FIG. 3 is a plan view that shows the inside of a processing chamber (electrolytic polishing chamber) 54 of FIG. 2. This electrolytic polishing apparatus, by carrying out copper plating on a surface of the substrate shown in FIG. 1B, fills copper 34 as an interconnect metal into via holes 26 and trenches 28 as interconnect recesses. Along with this, it prepares a substrate (polishing object) W that consists of the copper 34 deposited on a hard mask 24. Polishing of the surface of this substrate W is carried out to remove the copper 34 (and seed film 32) as a conductive material on the hard mask 24, thereby exposing a barrier film 30, as shown in FIG. 1C. Further, by removing the barrier film 30 on the hard mask 24, upper-layer interconnects 36 composed of the copper 34 are formed in insulating films 20, 22 as shown in FIG. 1D.

As shown in FIGS. 2 and 3, the electrolytic polishing apparatus includes a rotatable polishing table (turntable) 50, a vertically movable and rotatable substrate holder (polishing head) 52 for detachably holding the substrate W with its surface to be processed (formation surface of the copper 34) facing downward, and a bottomed cylindrical processing chamber 54 that surrounds the polishing table 50 and the substrate holder 52 to prevent scattering to the outside of liquid, such as an electrolytic solution or pure water, which is supplied to the upper surface of the polishing table 50 during or after polishing. The processing chamber 54 has in its sidewall a discharge outlet 54a for discharging the liquid accumulated in the chamber 54 to the outside. The substrate holder (polishing head) 52 is designed to be movable between a predetermined polishing position above the polishing table 50 and a substrate delivering/receiving position lateral to the polishing position.

A disk-shaped processing electrode 56, having such a size that it covers almost the entire area of the polishing table 50, is provided on the upper surface of the polishing table 50. The upper surface of the processing electrode 56 is entirely covered with a polishing pad (polishing cloth) 58 whose upper surface constitutes a polishing surface. The polishing pad 58 has a large number of vertical through-holes 58a so that the liquid, such as an electrolytic solution, supplied to the upper surface of the polishing table 50 is held within the polishing pad 58. During polishing, the processing electrode 56 is electrically connected to a conductive material, such as copper 34, provided on the surface of the substrate W via the electrolytic solution held in the through-holes 58a of the polishing pad 58.

Any polishing pad for CMP can be used as the polishing pad 58. In this embodiment, the polishing pad 58 is composed of IC-1000, manufactured by Nitta Haas Inc., having a large number of through-holes 58a all over the body. The entire polishing pad 58 may have lattice-shaped or annular grooves provided the pad has through-holes all over the body. If the polishing pad 58 itself is permeable to liquid, it may not necessarily have through-holes.

Regarding the type of the polishing pad 58, examples include an independent foam polyurethane pad and continuous foam suede pad. Also, in the case of using an electrolytic solution that does not contain abrasive grains, a fixed abrasive grain pad that binds grains that include cerium oxide (CeO₂), alumina (A₂O₃), silicon carbide (SiC), silicon oxide (SiO₂), zirconia (ZrO₂), iron oxide (FeO, Fe₃O₄), manganese oxide (MnO₂, Mn₂O₃), magnesium oxide (MgO), calcium oxide (CaO), barium oxide (BaO), zinc oxide (ZnO), barium carbonate (BaCO₃), calcium carbonate (CaCO₃), diamond (C) or a composite material thereof with a binding agent such as phenol resin, amino plant resin, urethane resin, epoxy resin, acrylic resin, acrylated isocyanurate resin, urea-formaldehyde resin, isocyanurate resin, acrylated urethane resin, acrylated epoxy resin and the like may be used as the polishing pad 58.

Here, regarding the shape of the grooves of the polishing pad 58, one or more concentric grooves, eccentric grooves, polygon grooves (including lattice grooves), spiral grooves, radial grooves, parallel grooves, arc grooves or combinations thereof may be formed. These groove shapes influence the retention and discharge of the electrolytic fluid. For example, concentric grooves and eccentric grooves have the effect of retaining the electrolytic fluid on the polishing pad 58 since the flow path is closed. In contrast, polygon grooves and radial grooves have the effect of promoting the inflow of the electrolytic fluid to the polishing object and discharge of the electrolytic fluid to the outside of the polishing pad 58. Note that in order to increase the efficiency of the inflow of the electrolytic fluid into the substrate surface, outflow and retention, the groove density distribution in the polishing pad 58 may be adjusted by suitably adjusting the groove width, groove pitch, and groove depth in the polishing pad 58 surface. For example, the groove width and depth may be 0.4 mm or more, and the groove pitch may be two times or more the groove width, and if the flow of the electrolytic fluid is considered, the groove width and groove depth are preferably 0.6 mm or more. Also, with the aim of activating the flow of the electrolytic fluid between grooves, an auxiliary groove may be provided between grooves (for example, forming a plurality of narrow grooves between concentric grooves, and forming a narrow groove between fat lattice grooves). Also, regarding the cross-sectional shape of the grooves, besides a square groove and a round groove, a V groove and, in consideration of the rotation direction of the polishing table on which the polishing pad 58 is mounted, when promoting the discharge of the electrolytic fluid from the grooves, a sequential groove that slants downstream in the rotation direction may be formed. Moreover, with the aim of holding the slurry, one or more through-holes may be formed in the surface of the polishing pad 58.

Also, the polishing pad 58 has one or a plurality of contact portions that make contact with the substrate on the polishing surface thereof. The shape of this contact portion influences the mechanical removal of the protective film that is generated by the electrolytic reaction. In order to increase the mechanical action at the contact surface, the shape of the contact portion may be made sharp, with other shapes including a cone shape, multi-pyramid shape, pyramid shape, and prism shape. Here, depending on the workpiece, when the shape of the contact portion becomes too sharp, it may lead to scratching and the like. As a measure to avoid this, a shape that planarizes the top surface so as to be a truncated cone or a truncated pyramid is included.

Also, the shape of the contact portion of the polishing pad that further reduces the mechanical action of the contact surface includes a cylinder, elliptic cylinder, and hemisphere. The arrangement of the contact portions may have regularity such as a lattice or alternating, triangular arrangement, or a random shape in order to remove regularity. Also, these contact portions may exist in a plurality or more within the polishing surface of the polishing pad, or their density distribution may be adjusted.

Above the polishing table 50 is disposed an electrolytic solution supply nozzle 60 for supplying the electrolytic solution to the upper surface of the polishing table 50 during polishing. The electrolytic solution supply nozzle 60 is connected to an electrolytic solution supply line 64 which extends from an electrolytic solution storage tank 62 for temporary storage of the electrolytic solution. In the supply line 64 is provided with an electrolytic solution supply part that is not illustrated, such as a tube pump, a diaphragm pump or a bellows pump. Above the polishing table 50 is also disposed a pure water supply nozzle 66 for supplying pure water for rinsing or cleaning to the upper surface of the polishing table 50 after polishing. The pure water supply nozzle 66 is connected to a pure water supply line (not illustrated).

Note that, in this embodiment, an additive component of the electrolytic solution, which easily precipitates or decomposes, is stored in a storage container 68 separate from the electrolytic solution storage tank 62. Then, while adding the additive component that is stored in the storage container 68 to the electrolytic solution stored in the electrolytic solution storage tank 62, the electrolytic solution that is adjusted into a predetermined condition is supplied from the electrolytic solution supply nozzle 60 to the upper surface of the polishing table 50. The electrolytic solution that has been prepared by the predetermined conditions and is stored in the electrolytic solution storage tank 62 may be directly supplied from the electrolytic solution supply nozzle 60 to the upper surface of the polishing table 50 without providing the storage container 68.

Located beside the polishing table 50 in the processing chamber 54, a columnar feeding electrode 70 is disposed such that its upper surface is approximately flush with the surface of the polishing pad 58. When the substrate holder 52 is lowered and the substrate W held by the substrate holder 52 is pressed against the polishing pad 58 at a predetermined pressure, the upper surface of the feeding electrode 70 comes into contact with the surface (lower surface) of the conductive material, such as the copper 34, at a peripheral portion of the substrate W, so that electricity is fed to the conductive material as a polishing object. The feeding electrode 70 is connected to one electrode of a power source 72 which is capable of controlling a voltage to be applied and its waveform, while the processing electrode 56 is connected to the other electrode of the power source 72. That is, in the case of performing electrolytic polishing of the metal interconnect such as the copper 34 of the substrate W, the feeding electrode 70 is connected to the anode of the power source 72, and the processing electrode 56 is connected to the cathode. In the case of performing electrolytic polishing of the barrier film 30 of the substrate W, the feeding electrode 70 is connected to the cathode of the power source 72, and the processing electrode 56 is connected to the anode.

In the case that the wetted surfaces of the conductive materials that come into contact with the electrolytic solution such as the polishing table 50, the feeding electrode 70, the processing electrode 56, a electric supply contact point 262, a second contact point 264, a conductive sheet 258 and the like do not become anodes, it is possible to use stainless steel, brass and the like for the material of the wetted surfaces. However, in the case that the wetted surfaces of the conductive materials become anodes, it is preferable that the material of the wetted surfaces have tolerance to anode oxidation. For example, it is preferable to perform a coating on the surface of the table and the electrodes to make them insoluble electrodes called DSE electrodes. For these, it is possible to favorably use a platinum-coated titanium electrode, an iridium-coated titanium electrode, a conductive diamond-coated electrode, a lead or lead alloy electrode, a high silicon cast iron electrode, a ferrite electrode and the like. Also, it is possible to favorably use a material that contains carbon.

A film thickness detection sensor 74 including, for example, an eddy current sensor for detecting a film thickness (remaining film thickness) of a conductive material such as copper 34 of the surface to be processed of the substrate W is embedded in the polishing table 50 with the upper surface of the sensor exposed on the surface of the processing electrode 56. An output signal from the film thickness detection sensor 74 is inputted into a control portion 76 via a slip ring not illustrated. Then, in this control portion 76, calculation processing is performed based on the input signal, and as a result an output signal is generated. The power source 72, a table drive section 78 for rotating the polishing table 50, a holder drive section 80 for rotating and vertically moving a substrate holder 52, and the like are controlled by the output signal from the control section 76.

The film thickness detection sensor 74 also detects an end point of polishing by sensing of the film thickness of conductive material, and outputs a signal to terminate polishing. In terminating polishing, the timing to stop the applied voltage may consist of first stopping the application of a voltage and then stopping the supply of the electrolytic solution. This order is preferred in order to not impair the polishing performance. As a method of detecting the remaining film thickness of the conductive film, in addition to an eddy current sensor, an optical monitor or fluorescent X-ray film thickness measurement, or voltage/current changes may be utilized.

An optical monitor utilizes the fact that reflected light intensity changes by optical interference. It is possible to use a method of irradiating measurement light through a pad hole from the light source embedded in the table, or a method of measuring a substrate in the state of being overhanged to the outside of the polishing table.

Fluorescent X-ray film thickness measurement utilizes the fact that the intensity of fluorescent X-rays generated when irradiating primary X-rays on a measurement object changes with respect to the film thickness. During polishing, measurement is performed by irradiating on the conductive film 1-dimensional X rays embedded in the table.

Voltage/current changes utilize the fact that the electrical resistance changes in accordance with the film thickness of the conductive film of the measuring object. Either a method that measures changes in current with a fixed voltage and calculates the film thickness from the electrical resistance, or a method that conversely measures changes in voltage with a fixed current may be used. By monitoring voltage/current during polishing, it can be easily used.

Also, in the polishing of a conductive film on a barrier film or a conductive film that includes a barrier film on an insulating film, as a method of detecting the state of the conductive film being completely polished off (cleared state), in addition to the film thickness detection methods mentioned above, other methods include a method that detects changes in the polishing pad surface temperature or substrate surface temperature, a method that detects changes in the frictional force between the substrate and polishing pad, a method that detects changes of the surface image, a method that detects changes in the slurry and components of the electrolytic solution (oxide concentration of by-products, conductive film ion concentrations).

As a method of detecting changes in the polishing pad surface temperature or substrate surface temperature, it is possible to use a method that measures the pad surface temperature with a radiation thermometer or measures the temperature of the substrate surface via holes provided in the polishing pad with a radiation thermometer that is embedded in the table.

As a method of detecting changes in the frictional force between the substrate and the polishing pad, it is possible to uses a method that measures changes in the drive current of the table on which the polishing pad is mounted or the substrate holder, or changes over time in the oscillation amplitude of a specified frequency for the substrate holder.

As a method of detecting changes in the substrate surface image, it is possible to use a method that measures changes in color of the substrate surface via holes provided in the polishing pad via a color sensor that is provided in the table, and changes in a two-dimensional image of the substrate surface by a CCD.

As a method of detecting changes in the slurry or components of the electrolytic solution (oxide concentration of by-products, conductive film ion concentrations), it is possible to use a method that measures changes in the conductive film ion density in the polishing liquid that is discharged from the polishing table.

The composite electrolytic polishing apparatus that is shown in FIG. 2 and FIG. 3 can be used alone, or in conjunction with a CMP apparatus or another composite electrolytic polishing apparatus, may be used as a polishing apparatus that has a plurality of polishing tables. In this case, it is possible to perform a series of polishing processes that combine CMP and composite electrolytic polishing with one polishing apparatus. In the case of having a plurality of polishing tables, the polishing table is preferably constituted with two to four tables, and in particular preferably two tables or four tables.

Next, a description will be made of electrolytic polishing with the electrolytic polishing apparatus shown in FIG. 2 and FIG. 3.

### (Metal Interconnect Layer Removal Process)

First, the substrate W with its surface to be processed facing downward is held in the substrate holder 52. Next, the substrate holder 52 is positioned at a predetermined position above the polishing table 50 in the state of holding the substrate W. Next, while rotating the polishing table 50, an electrolytic solution is supplied from the electrolytic solution supply nozzle 60 to the upper surface of the polishing table 50. At the same time, while rotating the substrate holder 52 together with the substrate W, the substrate holder 52 is lowered to press the surface to be processed of the substrate W against the polishing pad 58 at a predetermined pressure. When the feeding electrode 70 comes into contact with the surface copper 34 of the surface to be processed of the substrate W, the feeding electrode 70 is connected to the anode of the power source 72 and the processing electrode 56 is connected to the cathode of the power source 72. Then, a predetermined voltage is applied between the processing electrode 56 and the copper 34 of the surface to be processed of the substrate W. Thereby, an electrolytic reaction is generated at the surface of the copper 34, serving as an anode, to polish the copper 34. Note that during the polishing, the space between the processing electrode 56 and the surface of the copper 34 of the substrate W is filled with the electrolytic solution through the through-holes 58a provided in the polishing pad 58.

That is, during polishing, the surface of the copper 34 of the substrate W, serving as the anode, is anodically oxidized while a protective film is formed on the surface of the copper 34 by a corrosion inhibitor and a water-soluble polymeric compound in the electrolytic solution. The copper 34 of the substrate W, which is being pressed on the polishing pad 58, moves relative to the polishing pad 58 by the rotational movement of the substrate W and the rotational movement of the polishing table 50, and is thus mechanically polished. The protective film formed on recessed portions present in the surface of the copper 34 of the substrate W is not removed, and electrolytic polishing proceeds only on the protective film formed on raised portions present in the surface of the copper 34. By thus selectively removing only the protective film on the raised portions among the protective film formed on the surface irregularities existing on the surface of the copper 34 of the substrate W, the copper 34 is polished while planarizing its surface.

An example of an electrolytic solution for metal interconnect polishing is an aqueous solution that includes (1) 2 to 80% by weight of an organic acid, (2) 2 to 20% by weight of a strong acid having a sulfonic acid group, (3) 0.01 to 1% by weight of a corrosion inhibitor, (4) 0.01 to 1% by weight of a water-soluble polymeric compound, (5) 0.01 to 2% by weight of abrasive particles, (6) 0.01 to 1% by weight of a surfactant. The aqueous solvent may be deionized water, preferably ultrapure water. In addition, it is possible to use any electrolytic solution given in Table 2. The percentages shown in Table 2 are % by weight of the relevant components.

TABLE 2
Electrolytic Liquid Used in the Process of Removing Metal Interconnect

| | | Methane- | | Polyacrylic | | Surfactant | | |
|---|---|---|---|---|---|---|---|---|
| | Malonic | sulfonic | Benzo- | Ammonium | | MX- | Abrasive | |
| No. | Acid | Acid | triazole | (Mw 5000) | Methanol | 2045L | Particles | pH |
| 1 | 1M | 1.4M | 0.2% | 0.6% | 0% | 0.05% | 0.05% | 4.5 |
| 2 | 1M | 1.4M | 0.3% | 0.6% | 0.5% | 0.05% | 0.05% | 4.3 |
| 3 | 1M | 1.4M | 0.4% | 0.6% | 0.5% | 0.05% | 0.05% | 4.5 |
| 4 | 1M | 1.4M | 0.4% | 0.6% | 0.5% | 0.05% | 0.05% | 4.5 |
| 5 | 1M | 1.4M | 0.5% | 0.5% | 0% | 0.05% | 0.05% | 4.5 |
| 6 | 1M | 1.4M | 0.5% | 0.5% | 0% | 0.05% | 0.05% | 4.5 |

Electrolytic polishing using the electrolytic solution of the present invention preferentially processes raised portions of irregularities present in a surface of a conductive material, such as copper, formed over a surface of a workpiece, such as a substrate, while protecting recessed portions of the irregularities with a corrosion inhibitor, thereby processing and planarizing the surface of the conductive material. This method is particularly effective in the case of performing electrochemical mechanical polishing which consists of elctrolytically polishing a surface of a conductive material while rubbing the surface with a polishing pad. That is, a protective film is first formed by a corrosion inhibitor on a surface a conductive material to prevent excessive etching, followed by rubbing of the surface of the conductive material with a polishing pad having appropriate hardness and flatness. Thereby the protective film formed on the surfaces of raised portions of the conductive material is selectively removed while leaving the protective film formed on the surfaces of recessed portions of the conductive material. By subsequent electrolytic polishing of the conductive material, the raised portions of the conductive material can be preferentially processed, whereby the surface irregularities of the conductive material can be smoothed out.

For example, the preferred applied voltage when using the No. 1 electrolytic solution of Table 2 is 1 V to 50 V, and more preferably 2 V to 10 V. When the applied voltage is low, the desired polishing rate is not obtained, and when too high etch pits occur and the planarizing effect falls. The most preferable applied voltage is 4 V. In this case, a polishing rate of 600 nm/min to 1000 nm/min is obtained.

### (Barrier Film Polishing Process)

After completion of the electrolytic polishing of the metal interconnect, the processing electrode 56 and the feeding electrode 70 are disconnected from the power source 72, and the supply of the electrolytic solution is stopped. After that, the substrate holder 52 is raised. Thereafter, the electrolytic solution for polishing the barrier film is supplied to the pad. Then, the polarities of the feeding electrode 70 and the processing electrode 56 are switched (that is, the feeding electrode 70 is connected to the cathode of the power source 72, and the processing electrode 56 is connected to the anode of the power source 72). Then, the substrate holder 52 is lowered and thereby comes into contact with the polishing pad and undergoes relative movement therewith. Voltage is then applied to perform polishing of the barrier film. The polishing here is performed similarly to the aforementioned metal interconnect layer removal process except for the point of changing the electrolytic solution by reversing the polarity of the electrodes.

After completion of the electrolytic polishing of the barrier film, the processing electrode 56 and the feeding electrode 70 are disconnected from the power source 72. After stopping the supply of the electrolytic solution, the substrate holder 52 is raised. After an appropriate time, the substrate W after polishing is then transported to the next process by the substrate holder 52.

Note that the exchange of the electrolytic solution used for the electrolytic polishing of the metal interconnect layer (copper) and the electrolytic solution used for the electrolytic polishing of the barrier film is preferably performed in the following manner. When changing the target of the electrolytic polishing from the metal interconnect to the barrier film, the supply of electrolytic solution for the metal interconnect film is stopped. After that, pure water is supplied to the polishing pad, and voltage is not applied. The polishing pad and the substrate W are made to move relative to each other at a predetermined polishing pressure, and the electrolytic solution that remains on the polishing pad and the substrate is removed. Then, the substrate holder 52 is raised as described above, and the electrolytic solution for use in polishing of the barrier film is supplied to the polishing pad. Switching of the polarities of the processing electrode 56 and the feeding electrode 70 can be performed using a power source that allows polarity switching or using a polarity changeover switch.

Also, the same polishing liquid may be used without the need for changing the electrolytic solution for polishing of the metal interconnect layer (copper) and the polishing of the barrier film. In that case, it is possible to perform a series of processes by switching the polarity of the feeding electrode 70 and the processing electrode 56 in the state of continuing the contact and relative movement of the substrate W and the polishing pad.

Moreover, in the above example, the example was shown of switching the polarity by using a single power source. However, a method that switches these using a plurality of power sources and a plurality of processing electrodes or a plurality of feeding electrodes is possible.

Also, in the above-mentioned example, the example was shown of performing polishing of a metal interconnect (copper) and polishing of a barrier film with a single polishing table. However, after the completion of polishing of the metal interconnect, it is possible to perform polishing of the barrier film using a separate polishing table. In this case, it is possible to use a polishing apparatus that has a plurality of polishing tables.

The electrolyte solution (electrolytic solution) that is used in the barrier film electrolytic polishing process preferably has an electrolyte and/or a complexing agent as main components, with these dissolved in a solvent. Note that it is possible to also use an electrolytic solution in which the complexing agent also possesses the function of an electrolyte, and an electrolytic solution that consists of only a complexing agent. Also, is possible to add a polymer (water-soluble polymeric compound) and abrasive particles as required.

As the electrolyte, it is possible to preferably use at least one or a combination selected from potassium fluoride, lithium fluoride, ammonium fluoride, hydrofluoric acid, hydrochloric acid, hydrobromic acid, hydroiodic acid, sulfurous acid, sulfuric acid, disulfuric acid, alkyl sulfonic acid, benzenesulfonic acid, nitric acid, orthophosphoric acid, diphosphoric acid, triphosphoric acid, polyphosphoric acid, hypophosphoric acid, phosphorous acid, phosphinic acid, amino trimethylene phosphonic acid, hexafluorosilicic acid, hexafluorosilicic acid ammonium fluoride, hexafluorosilicic acid potassium, hexa fluorophosphoric acid, hexa fluorophosphoric acid ammonium, hexa fluorophosphoric acid potassium, hexa fluorophosphoric acid lithium, tetrafluoroboric acid, tetrafluoroboric acid tetra n-butyl ammonium, tetrafluoroboric acid copper (II), phthalic acid, tetraboric acid and their salts, potassium hydroxide, sodium hydroxide, lithium hydroxide, ammonia, trimethylammonium hydroxide, and 2-hidoroxyethyl-trimethyl ammonium hydroxide.

As the complexing agent, it is possible to use at least one or a combination selected from ethylenediaminetetraacetic acid (EDTA), dihydroxy ethyl ethylenediamine diacetic acid (DHEDDA), 1,3-propanediamine 4 acetic acid (1,3-PDTA), diethylenetriamine 5 acetic acid (DTPA), triethylenetetramine 6 acetic acid (TTHA), nitrilotriacetic acid (NTA), hydroxyethyl iminodiacetic acid (HIMDA), L-aspartic acid N, N-diacetic acid (ASDA), amino trimethylene phosphonic acid (NTMP), hydroxyl ethyl ethylenediamine tri-acetic acid (HEDTA), hydroxy ethylidene diphosphoric acid (HEDP), nitrilotris (methylene) phosphonic acid (NTMP), phosphonobutane tricarboxylic acid (PBTC), N,N,N′,N′-tetrakis (phosphonomethyl)ethylenediamine (EDTMP). Also, it is possible to use an organic acid as the complexing agent, including a carboxylic acid having a single carboxyl group, specifically formic acid, acetic acid, propionic acid, n-butyric acid, isobutyric acid, n-valeric acid, isovaleric acid, sorbic acid, glyoxylic acid, pyruvic acid, levulinic acid, benzoic acid, meta toluoylic acid, and acetylsalicylic acid. Also, a carboxylic acid having two or more carboxyl groups is included, specifically oxalic acid, malonic acid, succinic acid, glutaric acid, adipic acid, pimelic acid, suberic acid, maleic acid, fumaric acid, citraconic acid, mesaconic acid, itaconic acid, alpha-ketoglutaric acid, aconitic acid, phthalic acid, and pyromellitic acid. Also, a carboxylic acid which has one or more carboxyl groups and hydroxy groups is included, specifically citric acid, glycolic acid, lactic acid, gluconic acid, malic acid, tartaric acid, oxalacetic acid, salicylic acid, m-hydroxybenzoic acid, gentisic acid, protocatechuic acid, gallic acid, glucuronic acid, sialic acid, ascorbic acid, and the like. It is also possible to use salts of these carboxylic acids. It is possible to use one type alone or two or more types blended together. Moreover, it is possible to use as the complexing agent amino acid, specifically glycine, alanine, valine, leucine, isoleucine, serine, threonine, cysteine, methionine, asparagine, glutamine, proline, phenylalanine, thyrosin, tryptophan, aspartic acid, glutamic acid, lysine, arginine, histidine, and the like. It is possible to use one type alone or two or more types blended together.

As the solvent, it is possible to include nonpolar solvents such as benzene, toluene, diethyl ether, chloroform, ethyl acetate, tetrahydrofuran, and methylene chloride, and polar solvents such as water, methanol, and ethanol, acetone, acetonitrile, N,N-dimethylform-amide, dimethyl sulfoxide, acetic acid, and the like. Water is particularly preferred.

The concentration of the electrolyte in the electrolytic solution which can be used in a present invention is preferably 0.1 mol/L to 5.0 mol/L, and particularly 1.0 mol/L to 4.5 mol/L. If the electrolytic concentration is too thin, since it becomes difficult for an electrical current to pass through the electrolytic solution, there is the disadvantage of an electrolysis reaction not being performed. On the other hand, if the electrolytic concentration is too concentrated, the electrolyte may become saturated in the solution, with precipitation occurring that leads to contamination or the precipitate damaging the substrate.

The blending ratio of the electrolyte and the complexing agent is 0.001 to 100 mass parts of the complexing agent to 100 mass parts of the electrolyte, with 0.05 to 80 mass parts being particularly preferred. The complexing agent exhibits the action of stably dissolving a metal in the solution.

As a polymer (water-soluble polymeric compound) that is used as needed, it is possible to use one or more types selected from polyacrylic acid or its salt, polymethacrylic acid or its salt, polyethylene glycols, polyisopropylacrylamide, polydimethylacrylamide, polymethacrylamide, polymethoxyethylene, polyvinyl alcohol, hydroxyethyl cellulose, carboxymethyl cellulose, polyvinylpyrrolidone, and the like.

As an abrasive grain used if needed, oxidation silicon, aluminum oxide, manganese oxide, titanium oxide, cerium oxide, zirconium oxide, calcium fluoride, and the like can be favorably listed.

The electrolytic solution that is particularly preferably used in the barrier film electrolytic polishing process of the present invention is an aqueous solution of 0.5 mol/L orthophosphoric acid and 0.1 mol/L potassium fluoride, or 0.5 mol/L orthophosphoric acid and 0.1 mol/LEDTA (ethylenediaminetetraacetic acid).

When polishing the tantalum which is a barrier film using this electrolytic solution, the applied voltage is preferably 0.01 V or more and 500 V or less, and more preferably 0.1 V or more and 50 V or less. Particularly preferred is 1 V or more and 10 V or less. This is because when the voltage is lower than 1 V, the polishing rate is slowed, and when it is higher than 10 V, the current efficiency (the ratio of the current that is used for the reaction in connection with polishing of a barrier film among the flowing total current) decreases, and heat generation becomes intense. The most preferred is 5 V.

Also, as a method of applying a voltage to the substrate in the metal interconnect layer electrolytic polishing process and the barrier film electrolytic polishing process, in addition to a method that passes a direct current, it is also possible to adopt a method that utilizes a pulse wave, for example a sine wave, a square wave, a triangular wave, a serrated wave, and the like. Note that the voltage value of the pulse wave, sine wave, square wave, triangular wave, serrated wave and the like changes with respect to time, but the positive/negative polarity thereof does not change.

The method of carrying out electrolytic polishing of a substrate of the present invention includes a process of removing the metal interconnect layer as a preceding process or succeeding process of the aforementioned barrier film electrolytic polishing process. As a process of removing the metal interconnect layer, besides the aforementioned electrolytic polishing, it is also possible to carry out chemical mechanical polishing (CMP) or etching processing.

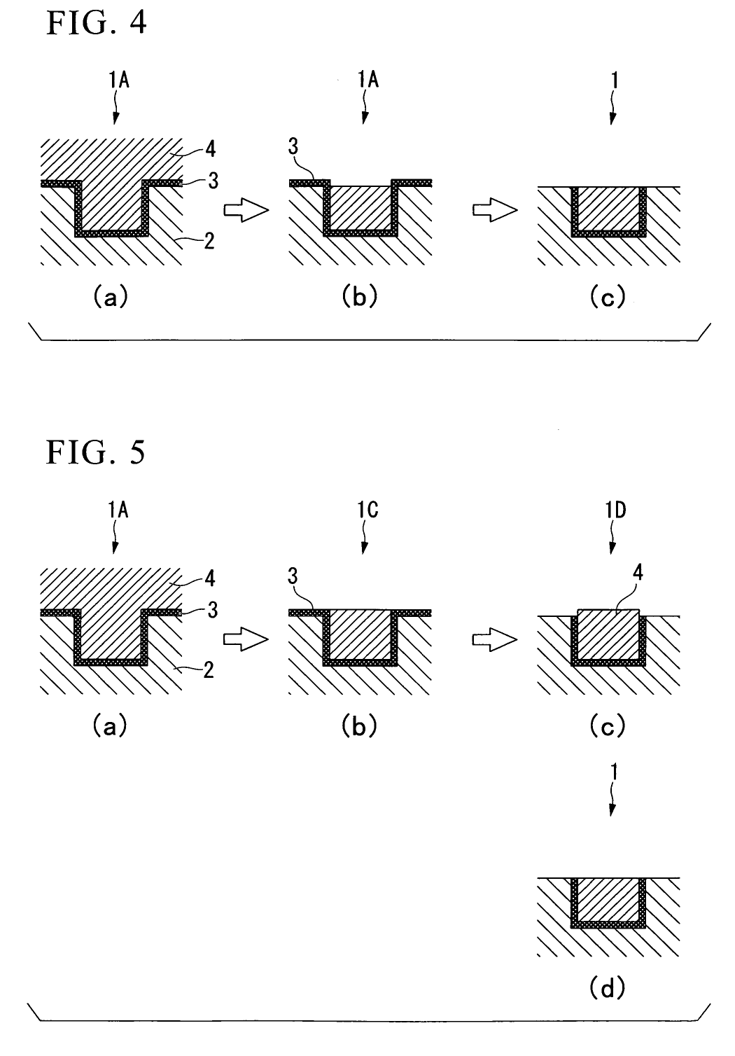

In the case of performing the metal interconnect removal process as a preceding process of the barrier film electrolytic polishing process, it is possible to carry out A processing method shown in FIG. 4 (removal of the metal interconnect layer, removal of the barrier film, final substrate) or B processing method shown in FIG. 5 (removal of the metal interconnect layer, removal of the barrier film, removal of metal interconnect, final substrate). In the case of carrying out as a succeeding process, it is possible to carry out the B process method.

A description will now be given of the method of carrying out electrolytic polishing of the substrate of the present invention referring to FIG. 4 and FIG. 5.

An interconnect groove is provided in an interlayer insulating film 2 in a substrate 1A. A barrier film 3 is laminated along this interconnect groove. A metal interconnect layer 4 is formed on the barrier film 3 ((a) of FIG. 4 and (a) of FIG. 5).

The following processes are performed in the A process method shown in FIG. 4. First, the metal interconnect layer removal process is performed that exposes the barrier film 3 by excessively removing the metal interconnect layer 4 by an amount equal to the thickness of the barrier film 3 using electrolytic polishing, chemical mechanical polishing, or etching processing which uses the substrate 1A as an anode ((b) of FIG. 4). Next, the barrier film electrolytic polishing process is carried out that applies a voltage with the substrate 1B serving as a cathode to remove only the barrier film 3 by dissolution and reduce the metal interconnect. As a result, a substrate 1 is obtained in which the barrier film of the surface of a substrate is removed, and even if a damage layer (an oxide film formed on the outermost surface of the metal interconnect) exists on the metal interconnect surface, it is repaired and the surface is planarized ((c) of FIG. 4).

The following processes are performed in the B process method shown in FIG. 5. First, the metal interconnect layer 4 is removed until becoming the same height as the barrier film 3 by an amount equal to the thickness of the barrier film 3 using electrolytic polishing, chemical mechanical polishing, or etching processing which uses the substrate 1A as an anode ((b) of FIG. 5). Next, a voltage is applied with the substrate 1C in which the metal interconnect layer 4 and the barrier film 3 are exposed serving as the cathode. Thereby, the barrier film electrolytic polishing process is carried out that removes only the barrier film 3 by dissolution and reduces the metal interconnect. Thereby, a substrate 1D is obtained in which the metal interconnect layer 4 remains as a raised portion that projects beyond the surface of the interlayer insulating film 2 ((c) of FIG. 5). Moreover, the metal interconnect layer 4 is removed until becoming the same height as the barrier film 3 by electrolytic polishing, chemical mechanical polishing, or etching processing which uses the substrate 1D as an anode ((d) of FIG. 5). In this way dishing is suppressed.

### SECOND EMBODIMENT

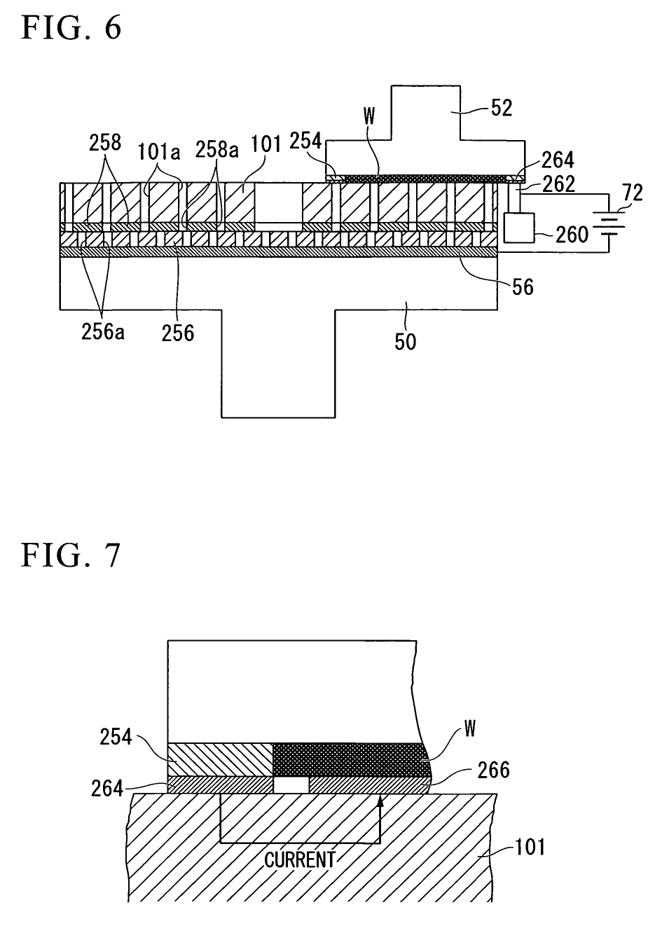

The first embodiment showed the example of using a pad with insulating properties as the polishing pad, but with the object of ensuring the electricity supply to the conductive film surface of the object to be polished, a pad with conductive properties that has a conductive surface on at least a portion of the polishing surface may be used. A preferred example in the case of using a conductive polishing pad will be described below with reference to FIG. 6 and FIG. 7.

FIG. 6 is a vertical sectional view showing an electrolytic polishing apparatus used in this process. In the electrolytic polishing apparatus shown in FIG. 6, members that are the same as or equivalent to those of the electrolytic polishing apparatus shown in FIG. 2 and FIG. 3 are designated by the same reference numerals and therefore overlapping descriptions shall be omitted.

On the upper surface of the polishing table 50, as shown in FIG. 6, a disk-shaped processing electrode 56 that is connected to one electrode of the power source 72 and an insulating surface plate 256 that covers the surface of the processing electrode 56 are laminated one after another. The surface of the insulating surface plate 256 is entirely covered with a polishing pad 101 (conductive pad). The upper surface of this polishing pad 101 constitutes a polishing surface. The inside of the insulating surface plate 256 has a large number of vertical through-holes 256a so that an electrolytic solution can flow into the interior.

This polishing pad 101 is constituted from a conductive material that has, for example, carbon as a main component so as to have conductivity. A plurality of through-holes 101a that are open for free passage vertically are provided in this polishing pad 101. Also, a retaining ring 254 that constitutes the periphery portion of the substrate holder 52 is provided. The retaining ring 254 is a projection portion for preventing the phenomenon in which the substrate W jumps out of the substrate holder 52, so-called slip out. As described below, electricity is fed from the second electrode 264 that is provided on the lower surface of the retaining ring 254 and contacts the electric supply contact point 262, through the polishing pad 101, to a conductive film such as a copper film 266 of the substrate W that is held by the substrate holder 52. Then, the processing electrode 56 and a conductive film such as the copper film 266 and the like are electrically connected by electrolytic solution that is supplied from the electrolytic solution supply nozzle 60 to the polishing surface of the polishing pad 101 and flows into the through-holes 256a provided in the insulating surface plate 256 and the through-holes 101a provided in the polishing pad 101.

In this example, the conductive sheet 258 that consists of for example platinum is interposed between the insulating surface plate 256 and the polishing pad 101. This lessens variations in the electric-potential distribution on the polishing pad 101, and as a result reduces variations of the electric-potential distribution on the conductive film surface such as the copper film 266 of the substrate W. Through-holes 258a that pass through the electrolytic solution are provided in the conductive sheet 258 at positions facing the through-holes 256a that are provided in the insulating surface plate 256.

A support base 260 is disposed at a position on the side of the polishing table 50. The substrate holder 52 holds the substrate W in the state where a portion of the retaining ring 254 protrudes into the side of the polishing table 50. The electric supply contact point 262 that is connected to the other electrode of the power source 72 is attached at a position that faces the retaining ring 254. The upper surface of this electric supply contact point 262 and the upper surface (polishing surface) of the polishing pad 101 are nearly flush. The second electrode 264 that consists for example of platinum is provided over the entire surface in a ring shape at the lower surface of the retaining ring 254. Note that a ring-shaped second electrode may be provided at a portion of the lower surface of the retaining ring 254.

Thereby, when the substrate holder 52 that holds the substrate W is lowered, a portion of the second electrode 264 that is provided on the lower surface of the retaining ring 254 makes contact with the upper surface of the electric supply contact point 262, and the greater portion makes contact with the upper surface of the polishing pad 101. Simultaneously, the conductive film of the cooper film 266 of the substrate W makes contact with the upper surface of the polishing pad 101. Thereby, as shown in FIG. 7, electricity is directly fed through the contact point 262, the second electrode 264, and the polishing pad 101 to a conductive film such as the copper film 266 of the substrate W that is held by the substrate holder 52. That is, charge carriers are transported to the conductive film by electron conduction along a route from the electric supply contact point 262 to the second electrode 264 provided on the retaining ring 254, from the second electrode 264 to the polishing pad 101, and from the polishing pad 101 to a conductive film such as the copper film 266. For this reason, the charge carriers are conveyed uniformly over the entire surface of the conductive film, and it is possible to reliably supply electricity even to an interconnect material that remains in the shape of an island and a barrier film with low conductivity.

Note this example provided the electric supply contact point 262, with electricity being supplied by making this electric supply contact point 262 come into contact with the second electrode 264 that is provided on the retaining ring 254. However, interconnect may be passed inside of the substrate holder 52, and via for example a rotary joint, the other electrode of the power source 72 may be directly connected to the second electrode 264 that is provided in the retaining ring 254. In this way, in the case of directly connecting the other electrode of the power source 72 to the second electrode 264 that is provided in the retaining ring 254, there is no need to hold the substrate W in the state of causing a portion of the retaining ring 254 to be hung out to the side of the polishing table 50.

Also, in the example, the conductive sheet 258 that consists of for example platinum is interposed between the polishing pad 101 and the insulating surface plate 256. Thereby, variations in the electric potential distribution of the polishing pad 101 are further lessened. That is, charge carriers that are transported to the second electrode 264 by making contact with the second electrode 264 are, after being once supplied to the polishing pad 101, more uniformly supplied to the entire surface of the polishing pad 101 by passing through the conductive sheet 258.

The through-holes 258a in the conductive sheet 258 are provided at positions facing the through-holes 101a of the polishing pad 101. The size of the through-holes 258a in the conductive sheet 258 is preferably smaller than the through-holes 101a of the polishing pad 101, and the contact surface area with the electrolytic solution is preferably small. This is because the greater the size of the through-holes 258a provided in the conductive sheet 258, the easier an electrolytic reaction occurs on the surface of the through-holes 258a, and the current efficiency (the ratio of the current that is used for polishing with respect to the flowing total current) decreases.

The material of the conductive sheet 258 is not limited to platinum, but the lower the electrical resistance of the conductive sheet 258 the better. Also, in the case of polishing for example a copper film, it is preferable that it be a material with a standard electrode potential that is higher than copper (ionization tendency smaller than copper). This is because in the case of the standard electrode potential of the material of the conductive sheet 258 that is spread under the polishing pad 101 being lower than copper (ionization tendency is greater than copper), this material becomes the main body of the electrolytic reaction, and so the copper is hindered from reacting.

Although as the shape of the conductive sheet 258 a sheet form is most preferred, a form in which innumerable thin wires are disposed is also acceptable, and a mesh form is also possible. As for the placement of the conductive sheet 258, the conductive sheet 258 may be merely sandwiched between the polishing pad 101 and the insulating surface plate 256. However, in order to prevent the occurrence of anodic reaction on the conductive sheet 258, it is preferable to coat the portions of the conductive sheet 258 that come into contact with the electrolytic solution with an insulating material so that the conductive sheet 258 does not come into contact with the electrolytic solution. In the case of a structure in which the conductive sheet 258 does not have a portion that comes into contact with the electrolytic solution, anode dissolution is not caused by the anodic polarization on the conductive sheet 258. For this reason, it is possible to form the conductive sheet with a material that has a lower electrode potential than the conductive film (workpiece) of a copper film or the like. The polishing pad 101 and the conductive liner sheet 258 are bonded with for example a conductive adhesive or the like.

Above was shown an example which supplies electricity to the polishing pad 101 having conductive properties through the second electrode 264 arranged on the lower surface of the retaining ring. However, the electric supply contact point 262 can directly supply electricity to the conductive pad or the conductive film on the substrate to be processed or the barrier film.

### THIRD EMBODIMENT

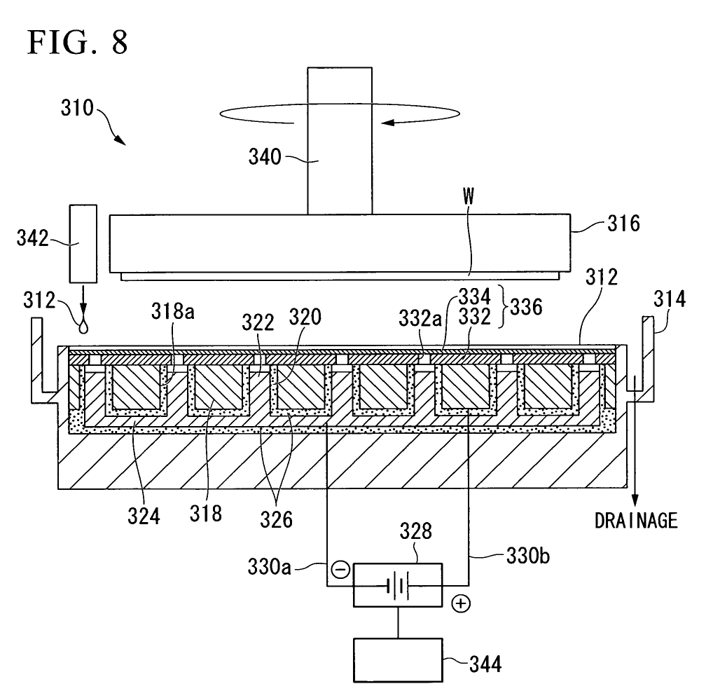

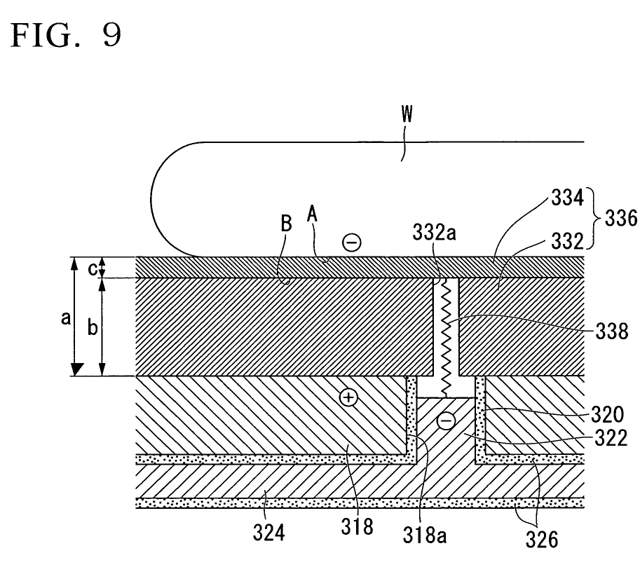

FIG. 8 and FIG. 9 show an example of still another electrolytic polishing apparatus that is capable of performing the barrier film electrolytic polishing process of the present invention. A description shall be given for the constitution of an electrolytic polishing apparatus 310 below. Note that composite electrolytic polishing is here used synonymously with electrolytic polishing.

The electrolytic polishing apparatus 310 has a bottomed cylindrical polishing tank 314 that is opened upward and holds an electrolytic solution 312 inside, and a substrate holding portion 316 that is disposed above the polishing tank 314 detachably holds the substrate W with its front surface (surface to be processed) facing downward.

The polishing tank 314 in this example is constituted so as to perform a scroll movement (sway-rocking motion) with driving of a motor and the like. A plate-shaped anode plate 318 which is immersed in an electrolytic solution 312 and serves as an anode is oriented horizontally at the bottom of the polishing tank 314. The anode plate 318 consists of a metal that is stable with respect to the electrolytic solution 312 such as SUS, Pt/Ti, Ir/Ti, Ti, Ta, and Nb and the like and is not passivated by electrolysis. A plurality of through-holes 318a which are open for free passage vertically are uniformly provided over the entire surface of the interior of this anode plate 318. The inner periphery surface of each through-hole 318a is covered with a cylindrical insulator 320. A cylindrical cathode 322 is laid inside of each cylindrical insulator 320 so that the upper surface thereof does not project upward from the upper surface of the anode plate 318. A plurality of these cathodes 322 are connected to each other at the rear surface of the anode plate 318 via an interconnect portion 324. Moreover, this interconnect portion 324 is covered in the state of being insulated from the anode plate 318 with the plate-shape insulators 326 that are integrally formed with the cylindrical insulator 320. This interconnect portion 324 is connected to the cathode terminal of a commutator 328 as a direct current and pulse current power supply disposed outside via wire 330a. The anode plate 318 is connected to the anode terminal of the commutator 328 through wire 330b. As for the cycle of pulse current, for example one from several seconds to several microseconds is used.

A non-conductive pad 332 which has liquid permeability by being constituted with a continuous foam body, nonwoven fabric, particle combination, and the like, and for example consists of polyurethane, vinylon, polyethylene, polyvinyl alcohol, polystyrene, polypropylene, and the like, is stuck to the upper surface of the anode plate 318. Moreover, a conductive pad 334 which is constituted with a continuous foam body, nonwoven fabric, particle combination, and the like, has liquid permeability, includes for example carbon or metal powder, and for example consists of polyurethane, vinylon, polyethylene, polyvinyl alcohol, polystyrene, polypropylene, and the like is stuck to the upper surface of this non-conductive pad 332. A polishing pad 336 is constituted by this non-conductive pad 332 and the conductive pad 334.

Moreover, a through-hole 332a which is open for free passage vertically is provided in the non-conductive pad 332 at a position facing each cathode 322, and in each through-hole 332a a conductor 338 that makes contact with the cathode 322 and the conductive pad 334 to electrically connect both is disposed at both ends. This conductor 338 is constituted from this example by the elastic body which has elasticity. With the elasticity that this conductor 338 itself has, both ends of the conductor 338 reliably make contact with the contact cathode 322 and the conductive pad 334.

The substrate holding portion 316 is connected to the lower end of a support rod 340 equipped with a rotating mechanism in which the rotational speed is controllable and with a vertical movement mechanism in which the polishing pressure is adjustable. The substrate W is adsorptively held by for example a vacuum absorption method at the lower surface thereof. Furthermore, an electrolytic solution supply portion 342 is provided above the polishing tank 314 and supplies the electrolytic solution 312 to the interior thereof. In addition, a control unit 344 that adjusts and controls each device and the whole operation and a safety apparatus (not illustrated) and the like are provided.

For example, as shown in FIG. 9, a polishing pad 336 that consists of a non-conductive pad 332 of thickness b and a conductive pad 334 of thickness c is laminated on the surface of the anode plate (anode) 318. When a surface (lower surface) that is the surface to be processed of the substrate W is brought into contact with the surface of the conductive pad 334, the distance between the anode plate 318 and the surface A of the substrate W becomes the total a of the thickness b of the non-conductive pad 332 and the thickness c of the conductive pad 334 (=b+c). When the non-conductive pad 332 and the conductive pad 334 are both constituted with a continuous foam body, and an electrolytic solution is supplied between the anode plate 318 and the surface of the substrate W, the electrolytic solution fills this dimension a.

In this example, the anode plate 318 and the substrate W conduct electricity by the electrolytic solution that is held in the polishing pad 336, and the electrolytic polishing proceeds.

Note that a method of carrying out electrolytic polishing on a substrate of the present invention is not restricted to the above-described embodiment, and various modifications are possible within the scope that does not depart from the spirit of the invention.

According to the method of electrolytically polishing a substrate of the present invention, it is possible to dissolve and remove only the barrier film without excessively removing the metal interconnect. Accordingly, it is possible to freely adjust the processing selectivity ratio between the metal interconnect and the barrier film formation material. For example, in the case of selecting copper as the metal interconnect and titanium as the barrier film, by having the substrate serve as the cathode, it is possible to adjust conditions such as the voltage and the pH of the electrolytic solution to dissolve only the barrier film without dissolving the copper. In this case, when the removal selectivity ratio of copper and the barrier film is expressed in the form of a “copper:barrier film,” it is 0:1. Also, in the case where it is desired to process the copper, conversely the substrate serves as the anode, that is, the electric potential to be impressed is changed from negative to positive, whereby it is possible to set the removal selectivity ratio of copper and a barrier film to 1:0. In either case, depending on the type of electrolytic solution that is used (pH and chemical species) and the electric potential to be impressed, it is possible to adjust the processing selectivity ratio of the metal interconnect:barrier film over a wide range from 0.1 to 1:0 as needed. In particular, in the case of the metal interconnect:barrier film being 0:1, the formation of a multilayer interconnect with little dishing is possible.

Also, by using an electrochemical action for a barrier film polishing process, compared to the prior art, it is possible to reduce the mechanical action of the polishing pad and the like. Accordingly, it is possible to minimize the damage to a film with a low mechanical strength, such as a low-k film.

Moreover, in the barrier film electrolytic polishing process, the barrier film is processed but the metal interconnect is reduced without being oxidized. When a damage layer is formed on the exposed surface during processing of a preceding process of the metal interconnect (for example, CMP or electrochemical mechanical polishing (ECMP)), this damage layer can be repaired by reduction. In this way, since the metal interconnect is reduced, the burden of the subsequent washing process is substantially lightened.

### EXAMPLES

Hereinbelow, the present invention shall be further described in detail, but the present invention is not limited to this.

### (Evaluation Method)

A processing experiment was conducted using the electrolytic polishing apparatus that is capable of processing only a portion of a wafer corresponding to a 40-mm diameter area. This apparatus is capable of controlling the electrode potential of a metal film that is formed on the wafer. It performs processing by polishing the exposed metal film with a polishing pad attached to a polishing jig while applying a voltage. Processing of the metal film was carried out by rotating the polishing jig at 250 rpm while pressing the polishing pad against a substrate sample at a pressure of 0.5 psi (approximately 35 g/cm²). During processing, the electrode potential of the metal film was kept constant.

Measurement of the electrode potential was performed using an electrochemical measurement system HZ-3000 (Hokuto Denko Co. Ltd.). A silver/silver chloride electrode (Ag/AgCl) electrode was used for the reference electrode.

The polishing speed was calculated by measuring the film thickness before and after polishing with a film thickness measuring apparatus (VR120A; Hitachi Kokusai Electric Alpha).

### (Polishing Pad)

A polyurethane pad with lattice-shaped grooves provided in the surface (IC1000 with X-Y grooves, made by Nitta Haas Inc.) was used.

### (Substrate)

A titanium (Ti) substrate used in the experiments is a silicon substrate on which a SiO₂ film (with a thickness of 200 nm) is formed as the interlayer insulating film and furthermore a Ti film (having a thickness of 300 nm) is formed as the barrier film thereon.

A tantalum (Ta) substrate used in the experiments is a silicon substrate on which a SiO₂ film (with a thickness of 200 nm) is formed as the interlayer insulating film and furthermore a Ta film (having a thickness of 300 nm) is formed as the barrier film thereon.

A tantalum nitride (TaN) substrate used in the experiments is a silicon substrate on which a SiO₂ film (with a thickness of 200 nm) is formed as the interlayer insulating film and furthermore a TaN film (having a thickness of 300 nm) is formed as the barrier film thereon.

A copper (Cu) substrate used in the experiments is a silicon substrate on which a SiO₂ film (with a thickness of 200 nm) is formed as the interlayer insulating film, a Ta film (having a thickness of 30 nm) is formed as the barrier film thereon, and a Cu film (having a thickness 1000 nm) is formed as the metal interconnect layer.

### (Electrolytic Solution)

### (From Test Example 1 to Test Example 5)

0.5 mol/L orthophosphoric acid+0.1 mol/L potassium fluoride was dissolved in pure water, and the pH was adjusted by potassium hydroxide (pH3 in test example 2 to test example 5).

### (From Test Example 6 to Test Example 8)

0.5 mol/L orthophosphoric acid+0.1 mol/L ethylenediaminetetraacetic acid was dissolved in pure water, and the pH was adjusted by potassium hydroxide.

### (Counter Electrode)

Metallic foil of SUS316L that is immersed in an electrolytic solution was used as the anode.

### Test Example 1

With the substrate serving as a cathode, a voltage was applied so as to become −2.0 V vs Ag/AgCl (−2.196V vs SHE). In the case of ignoring the potential drop due to the electrolytic solution, the voltage between the anode-cathode becomes 3.76 V. Table 3 shows the result of confirming the effects due to pH fluctuation.

TABLE 3
Processing Speed of Each Wafer

| pH | TaN | Ti | Cu | Ta |
|---|---|---|---|---|
| 3 | 0 | 276 | 4 | 0 |
| 6 | 4 | 11 | 11 | 0 |
| 8 | 5 | 7 | 22 | 0 |

As shown in Table 3, the higher the pH of the tantalum nitride substrate, the higher the processing speed, with the copper substrate showing the same tendency. On the other hand, the lower the pH of the titanium substrate (that is, the more acidic), the higher the processing speed. Meanwhile, the tantalum substrate was hardly processed with this electrolytic solution.

### Test Example 2

The electrode potential was held at −4 V vs Ag/AgCl (−4.196 V vs SHE; 6.04 V at the inter-electrode voltage), and electrolytic polishing was carried out with the substrate serving as the cathode. On the titanium substrate, the titanium was removed at the polishing speed of 111 nm/min, while the copper substrate, at 0 nm/min, was not processed.

### Test Example 3

The electrode potential was held at −2 V vs Ag/AgCl (−2.196 V vs SHE; 3.76 V at the inter-electrode voltage), and electrolytic polishing was carried out with the substrate serving as the cathode. On the titanium substrate, the titanium was removed at the polishing speed of 276 nm/min, while the copper substrate was processed at 4 nm/min, and so the processing speed was extremely slow compared to the titanium substrate.

### Test Example 4

The electrode potential was held at −1 V vs Ag/AgCl (−1.196 V vs SHE; 1.5 V at the inter-electrode voltage), and electrolytic polishing was carried out with the substrate serving as the cathode. On the titanium substrate, the titanium was removed at the polishing speed of 74 nm/min, while the copper substrate was processed at 100 nm/min.

### Test Example 5

The electrode potential was held at 1 V vs Ag/AgCl (0.804 V vs SHE; 3 V at the inter-electrode voltage), and electrolytic polishing was carried out with the substrate serving as the anode. On the titanium substrate, the titanium was removed at the polishing speed of 152 nm/min, while on the copper substrate, copper was removed at the polishing speed of approximately 400 nm/min.

The above results are summarized in Table 4. As shown in Table 4, among the electrode potentials with the substrate serving as the cathode, in the case of being −2 V vs Ag/AgCl or less, the polishing speed of Ti was extremely high, and in 1 V vs Ag/AgCl with the substrate serving as the anode, the polishing speed of Cu was extremely high.

TABLE 4
Effect of Electrode Potential (Inter-electrode Voltage)

| | | Inter- | | | | |
|---|---|---|---|---|---|---|
| | | electrode | Polishing Speed | | | |
| | Electrode Potential | Voltage | Ti | | Cu | |
| Test Example 2 | −4 V vs Ag/AgCl | 6.04 V | 111 | nm/min | 0 | nm/min |
| Test Example 3 | −2 V vs Ag/AgCl | 3.76 V | 276 | nm/min | 4 | nm/min |
| Test Example 4 | −1 V vs Ag/AgCl | 1.5 V | 74 | nm/min | 171 | nm/min |
| Test Example 5 | 1 V vs Ag/AgCl | 3.0 V | 152 | nm/min | 400 | nm/min |

### Test Example 6

With the pH of the electrolytic solution at 6, the electrode potential was held at −2 V vs Ag/AgCl (−2.196 V vs SHE; 3.76 V at the inter-electrode voltage), and electrolytic polishing was carried out with the substrate serving as the cathode. On the tantalum substrate, the tantalum was removed at the polishing speed of 2 nm/min.

### Test Example 7

With the pH of the electrolytic solution at 8, the electrode potential was held at −2 V vs Ag/AgCl (−2.196 V vs SHE; 3.76 V at the inter-electrode voltage), and electrolytic polishing was carried out with the substrate serving as the cathode. On the tantalum substrate, the tantalum was removed at the polishing speed of 1 nrm/min.

### Test Example 8

With the pH of the electrolytic solution at 12, the electrode potential was held at −2 V vs Ag/AgCl (−2.196 V vs SHE; 3.76 V at the inter-electrode voltage), and electrolytic polishing was carried out with the substrate serving as the cathode. On the tantalum substrate, the tantalum was removed at the polishing speed of 22 nm/min.

In Test Example 6 to Test Example 8, the effect of pH on the polishing speed of tantalum was confirmed. It is generally known that tantalum is easy to dissolve in an alkali solution, and the fact that the processing speed is high at pH12 also shows this.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A method of electrolytic polishing of a substrate having a barrier film and an interconnect metal layer on a surface to be processed under the presence of an electrolytic solution, the method comprising a barrier film electrolytic polishing process which removes the barrier film by applying a voltage between a cathode and an anode, with the surface to be processed serving as the cathode, and causing relative motion between the surface to be processed and a polishing pad which faces and makes contact with the surface to be processed.

2. The electrolytic polishing method of a substrate according to claim 1, wherein in the barrier film electrolytic polishing process, the voltage which is applied between the cathode and the anode is 0.01 to 500 V.

3. The electrolytic polishing method of a substrate according to claim 1, wherein in the barrier film electrolytic polishing process, along with the barrier film being removed, the metal interconnect layer is reduced.

4. The electrolytic polishing method of a substrate according to claim 1, further comprising, before or after the barrier film electrolytic polishing process, a metal interconnect layer electrolytic polishing process which removes the metal interconnect layer which is exposed by applying a voltage between a second anode and a second cathode, with the surface to be processed of the substrate serving as the second anode.

5. The electrolytic polishing method of a substrate according to claim 1, wherein the barrier film is composed of a material selected from the group consisting of tungsten, titanium, tantalum, manganese, vanadium, chromium, their alloys, nitride, carbide, nitrogen carbide, nitrogen silicide, or a combination thereof, and
the metal interconnect layer is composed of a material selected from the group consisting of gold, silver, copper, ruthenium, rhodium, platinum, iridium or their alloys.

6. The electrolytic polishing method of a substrate according to claim 1, wherein
the electrolytic solution which is used in the barrier film electrolytic polishing process includes at least one of the following electrolytes or a combination thereof: hydrofluoric acid, potassium fluoride, lithium fluoride, ammonium fluoride, hydrochloric acid, hydrobromic acid, hydroiodic acid, sulfurous acid, sulfuric acid, disulfuric acid, alkyl sulfonic acid, benzenesulfonic acid, nitric acid, orthophosphoric acid, diphosphoric acid, triphosphoric acid, polyphosphoric acid, hypophosphoric acid, phosphorous acid, phosphinic acid, amino trimethylene phosphonic acid, hexafluorosilicic acid, hexafluorosilicic acid ammonium fluoride, hexafluorosilicic acid potassium, hexa fluorophosphoric acid, hexa fluorophosphoric acid ammonium, hexa fluorophosphoric acid potassium, hexa fluorophosphoric acid lithium, tetrafluoroboric acid, tetrafluoroboric acid tetra n-butyl ammonium, tetrafluoroboric acid copper (II), phthalic acid, tetraboric acid and their salts, potassium hydroxide, sodium hydroxide, lithium hydroxide, ammonia, trimethyl ammonium hydroxide, and 2-hidoroxyethyl-trimethyl ammonium hydroxide.

7. The electrolytic polishing method of a substrate according to claim 6, wherein
the electrolytic solution which is used in the barrier film electrolytic polishing process further includes at least one of the following complexing agents or a combination thereof: ethylenediaminetetraacetic acid (EDTA), dihydroxy ethyl ethylenediamine diacetic acid (DHEDDA), 1,3-propanediamine 4 acetic acid (1,3-PDTA), diethylenetriamine 5 acetic acid (DTPA), triethylenetetramine 6 acetic acid (TTHA), nitrilotriacetic acid (NTA), hydroxyethyl iminodiacetic acid (HIMDA), L-aspartic acid N,N-diacetic acid (ASDA), amino trimethylene phosphonic acid (NTMP), hydroxyl ethyl ethylenediamine tri-acetic acid (HEDTA), hydroxy ethylidene diphosphoric acid (HEDP), nitrilotris (methylene) phosphonic acid (NTMP), phosphonobutane tricarboxylic acid (PBTC), N,N,N′,N′-tetrakis (phosphonomethyl)ethylenediamine (EDTMP).

8. An electrolytic polishing method of a substrate having an interlayer insulating film, a barrier film, and an interconnect metal layer, the method comprising:
a metal interconnect electrolytic polishing process which removes the metal interconnect layer and exposes the barrier film by a process which includes at least either one of applying a chemical mechanical polishing to the substrate, etching the substrate, or performing an electrolytic polishing using the substrate with the exposed metal interconnect layer as an anode; and
a barrier film electrolytic polishing process which removes the barrier film, by applying a voltage under the presence of an electrolytic solution, between a cathode and a second anode, with the substrate in which the barrier film is exposed serving as the cathode, and causing relative motion between the surface to be processed on the substrate and a polishing pad which faces and makes contact with the surface to be processed.

9. The electrolytic polishing method of a substrate according to claim 8, further comprising a process which removes the metal interconnect layer which remains as a projection portion on the surface to be processed, and planarizes the surface of the substrate by a process which includes at least either one of applying chemical mechanical polishing to the substrate, etching the substrate, or performing an electrolytic polishing using the substrate as an anode.

10. The electrolytic polishing method of a substrate according to claim 8, wherein in the barrier film electrolytic polishing process, the voltage which is applied between the substrate and the anode is 0.01 to 500 V.

11. The electrolytic polishing method of a substrate according to claim 8, wherein in the barrier film electrolytic polishing process, the barrier film is removed, and the metal interconnect layer is reduced.

12. The electrolytic polishing method of a substrate according to claim 8, wherein the metal interconnect electrolytic polishing process is an electrolytic polishing process which is performed by applying a voltage of 1 to 50 V between the substrate and the cathode.

13. The electrolytic polishing method of a substrate according to claim 8, wherein the barrier film is composed of a material selected from the group consisting of tungsten, titanium, tantalum, manganese, vanadium, chromium or their alloy, nitride, carbide, nitrogen carbide, nitrogen silicide, or a combination thereof, and
the metal interconnect layer is composed of a material selected from the group consisting of gold, silver, copper, ruthenium, rhodium, platinum, and iridium or their alloy.

14. The electrolytic polishing method of a substrate according to claim 8, wherein
the electrolytic solution which is used in the barrier film electrolytic polishing process includes at least one of the following electrolytes or a combination thereof: hydrofluoric acid, potassium fluoride, lithium fluoride, ammonium fluoride, hydrochloric acid, hydrobromic acid, hydroiodic acid, sulfurous acid, sulfuric acid, disulfuric acid, alkyl sulfonic acid, benzenesulfonic acid, nitric acid, orthophosphoric acid, diphosphoric acid, triphosphoric acid, polyphosphoric acid, hypophosphoric acid, phosphorous acid, phosphinic acid, amino trimethylene phosphonic acid, hexafluorosilicic acid, hexafluorosilicic acid ammonium fluoride, hexafluorosilicic acid potassium, hexa fluorophosphoric acid, hexa fluorophosphoric acid ammonium, hexa fluorophosphoric acid potassium, hexa fluorophosphoric acid lithium, tetrafluoroboric acid, tetrafluoroboric acid tetra n-butyl ammonium, tetrafluoroboric acid copper (II), phthalic acid, tetraboric acid and their salts, potassium hydroxide, sodium hydroxide, lithium hydroxide, ammonia, trimethyl ammonium hydroxide, and 2-hidoroxyethyl-trimethyl ammonium hydroxide.

15. The electrolytic polishing method of a substrate according to claim 14, wherein
the electrolytic solution which is used in the barrier film electrolytic polishing process further includes at least one of the following complexing agents or a combination thereof: ethylenediaminetetraacetic acid (EDTA), dihydroxy ethyl ethylenediamine diacetic acid (DHEDDA), 1,3-propanediamine 4 acetic acid (1,3-PDTA), diethylenetriamine 5 acetic acid (DTPA), triethylenetetramine 6 acetic acid (TTHA), nitrilotriacetic acid (NTA), hydroxyethyl iminodiacetic acid (HIMDA), L-aspartic acid N,N-diacetic acid (ASDA), amino trimethylene phosphonic acid (NTMP), hydroxylethyl ethylenediamine tri-acetic acid (HEDTA), hydroxy ethylidene diphosphoric acid (HEDP), nitrilotris (methylene) phosphonic acid (NTMP), phosphonobutane tricarboxylic acid (PBTC), N,N,N′,N′-tetrakis (phosphonomethyl)ethylenediamine (EDTMP).

16. An electrolytic polishing apparatus, which immerses a substrate having a barrier film and a metal interconnect layer on a side of a surface to be processed, in an electrolytic solution, and conduct electrochemical machining, thereby conducting an electrolytic polishing process, the apparatus comprising:
a polishing table which places the polishing pad on the upper surface thereof;
an electrolytic solution supply nozzle which is capable of supplying an electrolytic solution on the polishing pad;
a substrate holder which holds the substrate;
a drive mechanism which drives the substrate holder; and
a processing electrode and a feeding electrode which are connected to a power supply,
wherein the apparatus removes the barrier film of the substrate by applying a voltage between a cathode and an anode, with the surface to be processed of the substrate serving as the anode and the processing electrode serving as the cathode, and causing relative motion between the substrate and the polishing pad by driving the substrate holder with the drive mechanism.

17. The apparatus according to claim 16, further comprising:
a sensor which detects the film thickness of the conductive material of the surface to be processed of the substrate and emits an output signal; and
a control portion which performs control calculation processing with the output signal from the sensor serving as an input signal, and based on the control calculation processing, emits a control signal.
